(19) United States
(12) Patent Application Publication
(10) Pub. No.: US 2008/0220558 A1
(43) Pub. Date: Sep. 11, 2008

(54) Plasma spraying for semiconductor grade silicon

(75) Inventors: Raanan Y. Zehavi, Sunnyvale, CA (US); James E. Boyle, Saratoga, CA (US)

Correspondence Address: Law Offices of Charles Guenzer, 2211 Park Boulevard, P.O. Box 60749, Palo Alto, CA, 94306, US

(73) Assignee: Integrated Photovoltaics, Inc., Sunnyvale, CA (US)

(21) Appl. No.: 12/074,651

(22) Filed: Mar. 5, 2008

Related U.S. Application Data
(60) Provisional application No. 60/893,684, filed on Mar. 8, 2007.

(51) Int. Cl. H01J 7/24; H01L 31/18

(52) U.S. Cl. 438/57; 315/111.21; 257/E31.012

(57) ABSTRACT

A plasma spray gun configured to spray semiconductor grade silicon to form semiconductor structures including p-n junctions includes silicon parts such as the cathode or anode or other parts facing the plasma or carrying the silicon powder having at least surface portions formed of high purity silicon. The semiconductor dopant may be included in the sprayed silicon.

### RELATED APPLICATION

This application claims benefit of provisional application 60/893,684, filed Mar. 8, 2007.

### FIELD OF THE INVENTION

The invention relates generally to plasma spraying. In particular, the invention relates to plasma spraying in the course of semiconductor fabrication.

### BACKGROUND ART

Plasma spraying is a well established technology in which powder of a selected material is entrained in a plasma-excited stream of an arc gas directed at a substrate to be coated. The powder is melted or vaporized within the plasma and coats the substrate with a continuous layer of the material of the powder. Usually the arc gas is inactive, such as argon, so only powder material coats the substrate. Plasma spraying is particularly useful for coating foreign substrates with a layer of a material having a high melting point and which is difficult to machine, for example, refractory metals. Suryanarayanan provides an overview of plasma spraying in his text “Plasma Spraying: Theory and Applications,” World Scientific (1993), incorporated herein by reference. Pawlowski provides another overview in his text “The Science and Engineering of Thermal Spray Coatings,” Wiley (1995), also incorporated herein by reference.

Plasma spraying of silicon has been suggested for two different application. Noguchi et al. in U.S. Pat. No. 5,211,76 disclose plasma spraying of a silicon adhesion layer in the formation of a silicon solar cell. Such a solar cell may be deposited on a low-cost substrate, whether glass, steel, or even plastic. Akani et al. describe the semiconductor properties of plasma sprayed silicon in “Influence of process parameters on the elecgrical properties of plasm-sprayed silicon,” Journal of Applied Physics, vol. 60, no. 1, 1 Jul. 1986, pp. 457-459. Boyle et al. in U.S. Pat. No. 7,074,693 disclose plasma spraying of a silicon bonding layer bridging a seam between two silicon members to form a structure used in semiconductor processing. Examples of such structures are a tubular silicon oven liner and a silicon support tower used in batch thermal processing.

To our knowledge, application of sprayed silicon to solar cells has never been commercialized.

### SUMMARY OF THE INVENTION

A plasma spray gun configured for spraying silicon includes parts having at least surface portions composed of silicon. Preferably, the silicon has an impurity level of heavy metals of less than 1 parts per billion atomic.

The plasma gun of the invention may be used to spray semiconductor grade silicon to form semiconductor structures including, for example, a p-n junction. The sprayed silicon may be doped to the respective semiconductor type. The silicon powder may be obtained by jet milling in a jet mill with silicon walls

### BRIEF DESCRIPTION OF THE DRAWINGS

FIG. 1 is a partially sectioned orthographic view of a plasma spray gun to which the invention has been applied.

FIG. 2 is an orthographic view of an injector and injector holder usable with the plasma spray gun of FIG. 1.

### DETAILED DESCRIPTION OF THE PREFERRED EMBODIMENTS

We believe that the plasma sprayed silicon used in any application involving a semiconductor must be highly pure and free of contaminants. We further believe that conventional plasma spray guns and silicon powder used in plasma spraying silicon introduce impurities in the sprayed film which deleteriously affect the eventual product, whether it be the silicon solar cell or a silicon integrated circuit thermally processed with fixture spray bonded together. Suryanarayanan in the above cited text has disclosed how the various metal impurity levels increase as silicon powder goes through a plasma spray gun.

High-purity silicon powder can be obtained by the method described by Zehavi et al. in U.S. patent application Ser. No. 11/782,201, filed Jul. 24, 2007. It involves jet milling of larger granules of silicon grown by chemical vapor deposition in a jet mill modified to incorporate some high-purity, semiconductor-grade silicon parts, particularly the walls of the milling chamber and other parts coming in contact with the powder or milling gas flow. The granules can be either ground from fragments of an ingot of virgin polysilicon (electronic grade silicon or EGS) otherwise used as feedstock for Czochralski growth of wafers or be obtained from MEMC Electronic Materials, Inc. of St. Louis, Mo. or Wacker of Berghausen, Germany as directly grown from silane and hydrogen in a fluidized bed reactor. Such material, if carefully selected has a total transition metal impurity of less than 10 ppba (part per billion atomic). We have achieved metal impurity levels in silicon powder milled from larger CVD pellets of less than 10 parts per million weight. We think the impurity levels can be further reduced. Note that these impurity levels do not include the levels of carbon, nitrogen, and oxygen, which are often in the ppm range but have little effect on semiconductivity.

For feedstock in a plasma spray gun, the granules of the silicon powder should have a size of few nanometers to hundreds of micrometers though many spray processes are optimized for powder sizes of 1 to 5 micrometers with at least 95% of the particles having a diameter of less than 10 micrometers. The small particles produce denser, higher-quality semiconductor films.

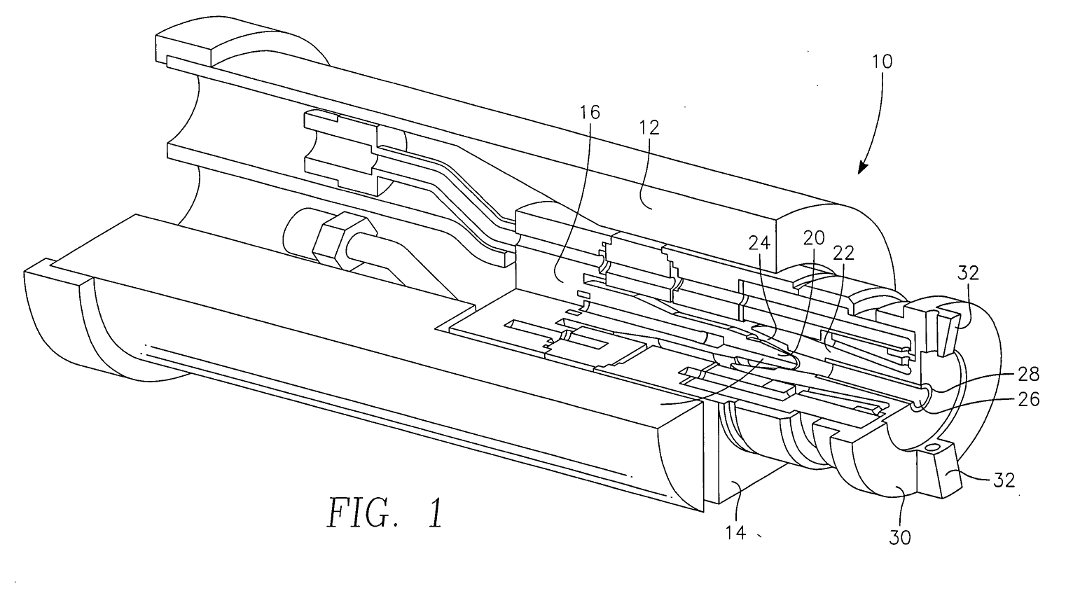

Conventional plasma spray guns can be retrofitted with one or more silicon electrodes or other parts exposed to the plasma or against which the powder may collide in order to reduce the impurities introduced in the spray silicon from the electrodes and parts. A plasma spray gun 10 illustrated in the partially sectioned orthographic view of FIG. 1 is commercially available from Sulzer Metco of Westbury, N.Y. as model F4-MB. It includes a housing 12 and a core 14 fixed inside the cover 12 and including a base extending through the bottom of the housing 12. A cathode 16 includes a tip 20 both arranged generally circularly symmetric about a gun axis. An anode 22 surrounds the tip 20 of the cathode 16 but is separated and electrically isolated from it by an annular gap 24. Insulating spacers separate the cathode 16 and anode 22. The anode 22 includes a nozzle 26 surrounding a tubular nozzle liner 28 extending to the exterior of the gun 10 along the gun axis along which the plasma beam travels. An inactive arc gas such as argon and/or helium is supplied to the back of the gap 24 and flows over the cathode tip 20 and out the nozzle 24.

The cathode 16 is negatively biased with respect to the anode 22. For example, the anode 22 is grounded and a negative DC voltage is applied to the cathode 16 of sufficient magnitude to excite the argon into a plasma as it flows between the two electrodes 16, 22. The plasma argon flows out of the gun 10 through the nozzle 26 toward a substrate being spray coated as a high-velocity beam having a velocity up to 3050 m/s.

The illustrated gun includes passages for cooling water although radiative cooling though fins may be satisfactory.

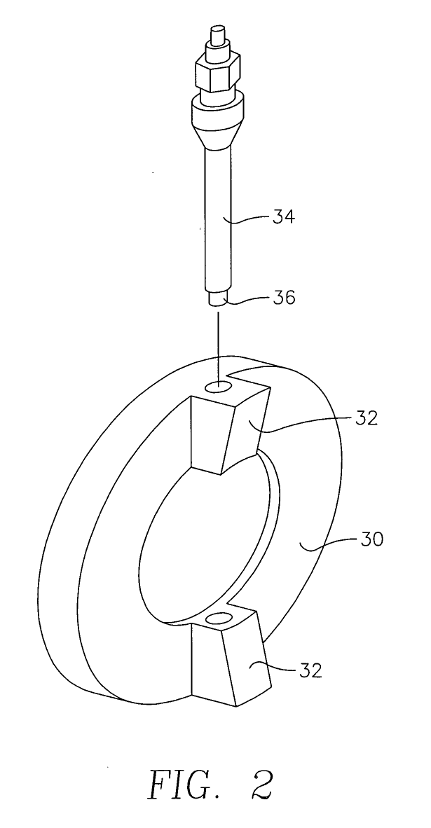

A powder injector holder 30 is fixed to the gun 10 at the outlet of the nozzle 26. As better illustrated in the orthographic view of FIG. 2, it includes two stubs 32 for supporting two powder injectors 34 with diametrically opposed injector tips 36 pointing toward the middle of the plasma beam exiting the nozzle 26. The mixing may be performed in a powder feeder, either the one available from Sulzer Metco or other similar ones specially designed for high purity. The carrier gas and entrained silicon powder are fed to the back of the powder injectors 34 and injected into the plasma beam through the tips 36. It is possible to drop the silicon powder into the plasma beam without the use of a carrier gas. The plasma beam quickly itself entrains the silicon powder and vaporizes or at least melts it since the plasma gas temperature may be as high as 18,000° C. as the beam exits the gun nozzle 26, far above the melting point of silicon of about 1410° C. or its boiling point of 2450° C. The gas temperatures within the external plasma beam quickly decrease away from the nozzle 26.

The vaporized or melted silicon entrained in the gun's plasma beam strikes the substrate and is coated on it while the argon diffuses away. The gun data sheet reports typical spray rates of 50 to 80 g/min and deposition efficiencies of 50 to 80%.

Conventionally, the cathode 16, anode 20, and nozzle liner 28 have been composed of brass and perhaps including a tungsten coating or insert. We think a better readily available metal for coating or insert for silicon plasma spray guns is molybdenum. The powder injectors have conventionally been composed of steel or carbide. We believe that these gun parts are being partially eroded during plasma spraying and the constituents are being coated together with the silicon. Especially the negatively biased cathode 16 is subject to sputtering of positive argon ions in the plasma. Heavy metal concentrations of greater than 1 ppma (parts per million atomic) in silicon are sufficient to seriously degrade its semiconductor characteristics. Copper in brass gun parts is particularly deleterious.

The performance of the gun can be improved by changing the composition of parts facing the plasma or carrying the silicon powder entrained in the carrier gas to silicon, especially high-purity silicon. That is, the cathode 16 and other degradable parts or at least their plasma facing surfaces should consist essentially of silicon having less than 1 parts per million atomic (ppma) and preferably less than 0.1 ppma of metal impurities. Silicon is available in purities of better than 1 ppba with reference to heavy metals. The silicon may be monocrystalline, for example, grown by the Czochralski method s used for semiconductor wafers, or may be polycrystalline. Polycrystalline silicon may be cast or also grown by the Czochralski method. A desirable form of polycrystalline silicon is randomly oriented polycrstalline silicon (ROPSi) grown by the Czochralski method using a randomly oriented seed and thereafter machined to final product, as described by Boyle et al. in U.S. patent application Ser. No. 11/328,438, filed Jan. 9, 2006 and published as U.S. patent application publication 2006/0211218. Another advantageous form of polycrystalline silicon is the previously described virgin polysilicon. Boyle et al. describes the machining of this highly stressed material in U.S. Pat. No. 6,617,225.

Powder purity is improved by assuring that the gas lines supplying the feed carrier gas and arc gas and the feeder supplying the powder to the feed supply gas do not substantially contaminate the silicon powder.

For fabrication of a semiconductor junction by plasma spraying, it is possible to control the doping of the sprayed layers by varying the doping of the powder, as described by Janowiecki et al. in U.S. Pat. No. 4,003,770 and by Gulko et al. in U.S. Pat. No. 4,101,923. Neither reference describe how doped silicon powder is obtained. We believe the powder can be doped in a diffusion furnace using, for example, phosphine or diborane as dopant gases to produce the selected conductivity type, as is conventionally done for wafers. Alternatively, the Czochralski or float zone silicon used in forming the powder may be grown with the proper doping introduced in the melt. Silicon powders of different doping types allow a siliconp-n junction to be fabricated perhaps even using the same plasma spray gun. It is also possible to form a p-i-n semiconductor structure, such as are favored for solar cells, by spraying an intermediate layer of undoped silicon powder.

An alternative method to control the doping of the sprayed silicon layers is to form parts of the plasma gun from doped silicon. In particular, the cathode of the plasma gun is subject to argon sputtering during the spraying operation. As a result, the silicon of the cathode enters the plasma beam at a controlled rate. Accordingly, if the silicon cathode is composed of n-doped or p-doped silicon, the sprayed silicon layer will be similarly doped, assuming that the silicon powder and other contaminants do not counter dope. Bulk doped parts can be obtained by using Czochralski or float zone silicon of the desired doping, as described above for doped silicon powder.

One complication of a silicon cathode or anode is that both electrodes need to be sufficiently electrically conductive to excite and maintain the plasma. Very pure silicon is considered resistive with a resistivity of, for example, greater than 10 ohm-centimeter. Several means may be employed to make the silicon electrodes conductive.

The previously discussed doped silicon electrodes may have a sufficient doping level, for example, resistivity less than 0.2 ohm-cm for either doping type to increase its resistivity even at room temperature to acceptable levels. However, the concentration of dopants in silicon is limited by the onset of segregation and at this concentration limit the doped silicon has significantly less electrical conductivity than a metal. Care must be taken to not initiate filamentary currents and fracturing the silicon electrodes.

Several other means rely on the fact that the electrical conductivity of lightly doped and essentially undoped silicon rises with temperature. Electrodes in plasma guns generally operate at relatively high temperatures to the extent that cooling is required. Accordingly, once an auxiliary source has heated the silicon electrode to its high operational temperature, typically about 600 to 700° C., the auxiliary heating may be removed.

One auxiliary heating means inductively couples RF energy into the silicon electrodes by an RF coil or antenna positioned outside the gun, similarly to the RF heating done in float zone purification of silicon ingots.

The gun can include embedded resistive heaters in thermal contact with the silicon electrodes.

Another auxiliary heating method initially passes a flammable gas through the normal argon flow path in the gun and ignites the gas to form a torch or flame adjacent the silicon electrodes. Once the electrodes have reached the requisite temperature, argon is substituted and power is applied to the electrodes to excite and maintain the argon plasma. The impedance of the electrode pair can be monitored during heating. The flammable gas may a fuel such as oxygen in combination with hydrogen, propane, or propylene, as described in Suryanarayanan's text for high-velocity oxygenated fuel.

The invention is not limited to the described plasma spray gun. The plasma can be excited by other means such as RF driven electrodes or by an RF-powered inductive coil. The tube around which the inductive coil is wrapped may be resistive, lowly doped silicon of high purity. The powder can alternatively be injected into the stream of the arc gas upstream or downstream from the plasma source region, perhaps in the nozzle region, or in the source region itself. Wire electrodes, for example, of silicon, may be used.

The entire conventional gun part does not need to be composed of silicon. The part can be redesigned to be composed of silicon only in the portion facing the plasma or silicon powder stream.

1. A plasma gun for exciting a plasma in a stream of an arc gas, a surface portion of at least one of parts of the gun facing the plasma or a flow of powder into the gun consisting essentially of silicon.

2. The plasma gun of claim 1, wherein the at least one part includes at least one electrode of multiple electrodes of the gun.

3. The plasma gun of claim 2, wherein one or more of the electrodes are doped to be conductive.

4. The plasma gun of claim 2, having auxiliary heating means for heating the one electrode to a temperature at which it can act as an electrode.

5. The plasma gun of claim 1, wherein the at least one part includes at least one powder injector for injecting powder into the stream and having at least a surface portion facing a flow of the powder consisting essentially of silicon.

6. A plasma spraying method, comprising:
exciting a plasma in a stream of an arc gas in a plasma gun having at least one electrode having a surface portion facing the plasma consisting essentially of silicon;
injecting silicon powder into the stream having a metal impurity level of less than 10 parts per million weight; and
directing the stream with the injected silicon to a substrate to form a silicon layer thereupon.

8. The method of claim 6, wherein the silicon layer forms part of a semiconductor device having a p-n junction.

9. The method of claim 8, wherein the semiconductor device comprises a solar cell.

10. The method of claim 6, wherein the silicon powder consists of particles 95% of which have diameters of less than 10 micrometers.

11. The method of claim 6, wherein chemical vapor deposition forms the large-particle silicon powder or a larger body ground into the suitably sized fine-particle size range of silicon powder.

12. The method of claim 6, further comprising the prior step of heating the surface portion to be electrically conductive.
